(19) United States
(12) Patent Application Publication
(10) Pub. No.: US 2013/0079230 A1
(43) Pub. Date: Mar. 28, 2013

(54) IONICALLY CONTROLLED THREE-GATE COMPONENT

(71) Applicants: Ulrich Poppe, Dueren (DE); Dieter Weber, Juelich (DE); Yuriy Divin, Juelich (DE); Mikhail Faley, Juelich (DE)

(72) Inventors: Ulrich Poppe, Dueren (DE); Dieter Weber, Juelich (DE); Yuriy Divin, Juelich (DE); Mikhail Faley, Juelich (DE)

(21) Appl. No.: 13/703,225

(22) PCT Filed: Jun. 3, 2011
(86) PCT No.: PCT/DE2011/001167

§ 371 Date: Dec. 10, 2012

(30) Foreign Application Priority Data
Jul. 5, 2010 (DE) 10 2010 026 098.3

(51) Int. Cl. H01L 39/22

(52) U.S. Cl. CPC H01L 39/223
USPC 505/190; 257/31

(57) ABSTRACT

A three-port component comprises a source electrode, a drain electrode, and a channel, which is corrected between the source electrode and the drain electrode and which is made of a material haying an electronic conductivity that can be varied by supplying and/or removing ions. The three-port component comprises an ion reservoir, which is in contact with a gate electrode, and which is connected to the channel so that the reservoir is able to exchange ions with the channel when a potential is applied to the gate electrode. Information can be stored on the three-port component by distributing the total number of ions, which are present in the ion reservoir and the channel, between the ion reservoir and the channel. The distribution of ions in the channel and the ion reservoir changes when, and only when, a corresponding driving potential is applied to the gate electrode. Thus, in contrast to RRAMS, there is no time-voltage dilemma.

The invention relates to a three-port component which can be switched by the movement of ions.

### PRIOR ART

Electrically erasable programmable read-only memories (EEPROMs) have become established as the standard for non-volatile rewritable electronic data memories. In general, they comprise a variety of field-effect transistors containing insulated gates. If a charge is stored on the gate, the field-effect transistor is conductive, which is represented by a logical 1. If the gate contains no charge, the field-effect transistor blocks any passage, which is represented by a logical 0. Information is written to the EEPROM by applying a high voltage pulse to a control electrode, which is insulated with respect to the gate by a barrier. Electrons can thus overcome the barrier, and a charge can be stored on the gate or withdrawn therefrom.

The drawback is that the barrier is subjected to a high load during every write process and, consequently, to progressive wear and tear, whereby the number of write processes of each field-effect transistor is limited. In addition, as the miniaturization of EEPROMs reaches physical limits, the likelihood that the stored charge is lost as a result of tunneling increases exponentially with the decrease in dimensions. The extent of the charges that must be transported to the gate constitutes the limiting factor for the speed at which this can be done.

Resistive memories (RRAMs) have therefore been developed as an alternative to EEPROMs. RRAMs are based on the principle of varying the electric resistance of an active material, which is disposed between two electrodes, between at least two stable states, by applying a high write voltage, and measuring the electric resistance by applying a lower read voltage. The review article (R. Waser, R, Dittmann, G. Staikov, K. Szot, “Redox-Based Resistive Switching Memories—Nanoionic Mechanisms, Prospects, and Challenges”, Advanced Materials 21 (25-26), 2632-2663 (2009)) provides an overview of the current development stage.

The drawback of RRAMs, in particular, is an unresolved tradeoff between the speed at which the information can be stored and read out and the long-term stability of the stored information.

### PROBLEM AND SOLUTION

It is therefore the object of the invention to provide a component that can both offer greater long-term stability and act as a fast memory.

This object is achieved according to the invention by a three-port component according to the main claim. Advantageous embodiments will be apparent from the dependent claims.

### SUBJECT MATTER OF THE INVENTION

Within the scope of the invention, a three-port component was developed. This three-port component comprises a source electrode, a drain electrode, and a channel, which is connected between the source electrode and the drain electrode and which is made of a material having an electronic conductivity that can be varied by supplying and/or removing ions.

In the present context, electronic conductivity shall be understood to also mean the properties of superconductivity that may be present in the channel, and in which Cooper pairs take the place of individual electrons. Hole conduction in a p-doped semiconductor shall also be considered to be covered by electronic conductivity as defined by the present invention.

According to the invention, the three-port component comprises an ion reservoir, which is in contact with a gate electrode, and which is connected to the channel so that the reservoir is able to change ions with the channel when a potential is applied to the gate electrode. The transport of ions between the ion reservoir and the channel changes the concentration of mobile ions in the channel. This doping changes the conductivity of the channel. Even a small change in the doping suffices to change the conductivity of the channel many fold. To this end, the ion reservoir may well act as a gate electrode, provided it is electronically conductive.

It was recognized that information can be stored in the three-port component by distributing the total number of ions, which are present in the ion reservoir and the channel, between the ion reservoir and the channel. The information can be stored in the component by varying the ion distribution, by applying a suitable potential to the gate electrode. This information can be read out non-destructively by measuring the electrical resistance between the source electrode and the drain electrode, if the diffusion of ions between the ion reservoir and the channel is sufficiently slow in the absence of a driving potential at the gate electrode, this memory is non-volatile.

The component can store, delete, and overwrite digital information. For this purpose, for example, a logical 1 may be encoded by the state in which the channel has a low electrical resistance and allows a high current to flow when a predetermined read voltage is applied. A logical 0 is then encoded by the state in which the channel has a high electrical resistance, so that only little current flows when the read voltage is applied. However, it is also possible to store any arbitrary intermediate values. The component is thus also suitable as a memory for analog information, such as measurement data, for example.

It was recognized that this form of storage solves a fundamental tradeoff of resistive memories (RRAMs). Conventional resistive memories are dual-port components, so that both the storing and the reading of information take place by applying voltages to the same electrodes. If a high write voltage is applied for storing, the resistance of the storage material changes. When a considerably lower read voltage is applied, this change is manifested in a change in the current that is driven through the memory by this read voltage.

The write voltage is limited to several volts by the dimensions of the memory and electronic requirements. On the other hand, the read voltage must be sufficiently high so as to be able to measure the resistance of the memory material with a sufficient signal-to-noise ratio. Read and write voltages may thus only differ from each other by approximately one order of magnitude.

At the same time, resistive memory element states are intended to remain stable over a period of at least 10 years, even if the read voltage is constantly applied, even though the element can be switched within a few nanoseconds by applying the write voltage. A voltage difference of only one order of magnitude is thus intended to cause a difference of approximately 10 orders of magnitude in the characteristic switching times. This tradeoff is known as the “voltage-time dilemma” in the expert community.

According to the invention, the additional gate electrode is provided for storing information. The distribution of ions between the channel and the ion reservoir changes when, and only when, a corresponding driving potential is applied to the gate electrode. The read voltage that is applied between the source electrode and drain electrode, in contrast, has no influence on the distribution of the ions, because no electric field is created between the channel and the ion reservoir during reading. Therefore, it is unnecessary to provide differing voltage levels for reading and for writing. This advantageously decreases the switching complexity. However, it is also possible for a current, which is considerably higher than the current flowing between the ion reservoir and the channel during writing, to flow through the channel during reading without triggering ion exchange between the channel and the ion reservoir.

If a potential, which is lower than would be necessary to trigger transport of ions between the ion reservoir and the channel, is applied to the gate electrode, the component acts as an amplifier, analogous to a field-effect transistor, and can be used as such an amplifier.

In a particularly advantageous embodiment of the invention, the ion reservoir is a solid body under standard conditions. This body can be crystalline, amorphous, or a polymer, for example. The ions can then essentially move within the ion reservoir and between the ion reservoir and channel, only by way of diffusion. Other transport mechanisms, such as the convection of a liquid or gaseous ion reservoir, are subordinate to diffusion. The diffusion in turn can be controlled by the potential that is present at the gate electrode, in conjunction with the temperature.

In general, any material that is able to give off cations and/or anions to the channel while preserving charge neutrality is a suitable ion reservoir. In particular, a material that comprises at least one cation/anion having variable valence has this capability. Another ion type may be loosely bound to such a cation/anion, or an unoccupied site for an ion of this type may be provided. This ion type can then be moved using comparatively little activation energy and can be exchanged between the ion reservoir and the channel. The ion which is exchanged between the ion reservoir and the channel can notably be oxidized or reduced, or ionized or deionized, during this exchange.

The ion reservoir, the ion conductor, and/or the channel advantageously have a crystal structure that does not change when ions are exchanged between the ion reservoir and the channel. As an alternative, the ion reservoir, the ion conductor, and/or the channel can also be amorphous.

It was recognized that many solid-state properties of the ion reservoir, the ion conductor, and/or the channel, and more particularly the electronic and ionic conductivities, are dependent on the respective crystal structure. If the transport of ions between the ion reservoir and the channel changes the crystal structure of one of these materials, the solid-state properties change. However, a well-ordered crystal structure generally requires complex techniques during production for introducing these into the material, and cannot automatically regenerate during operation. Any worsening of the crystal structure during the exchange of ions between the ion reservoir and channel is thus associated with irreversible wear of the respective material. The component can thus survive a particularly high number of write cycles, if the crystal structures of the ion reservoir, the ion conductor, and/or the channel either do not change during operation or are absent from the start because the respective material is amorphous. Amorphous materials, the properties of which are not dependent on a well-ordered crystal structure, offer an added advantage, during production of the component, in that the leeway for the process parameters is significantly greater.

A well-ordered crystal structure may contain sites that can receive and also give off ions without changing the crystal structure as a whole. For example, the ions can be intercalated in the material of the ion reservoir on interstitial sites, they can occupy vacant sites in the crystal lattice of the ion reservoir, or they can be mobile along crystal defects (such as dislocations, point defects, grain boundaries, or stacking faults).

The ion mobility of the ion reservoir at the usage temperature and the working field strength, which is predetermined by the voltage drop between the gate electrode and the channel, decisively determines the speed at which the conductivity of the channel can be varied.

If the ion conductor is not identical to the ion reservoir, the ion reservoir should have a sufficiently high electronic conductivity for the potential difference between the gate electrode and the channel to drop substantially across the ion conductor, so as to provide the activation energy for the transport of ions through the ion conductor. However, if the ion reservoir is also the ion conductor, it should have only a low electronic conductivity so as not to short-circuit the current path from the source electrode through the channel to the drain electrode. So as not to impede the change of the electronic conductivity in the channel effected by the exchange of ions between the ion reservoir and the channel, the electronic conductivity of an ion reservoir that also acts as the ion conductor should change during this exchange by at least one order of magnitude less than that of the channel.

Crystalline or amorphous solids having a high ion conductivity are particularly suitable as the ion reservoir. Among crystalline solids, perovskite structures are particularly advantageous, the crystal being composed of the same in cubic form or in the form of layers. Examples of such materials include SrFeO₃₋ₓ and LaNiO₃₋ₓ.

In SrFeO₃₋ₓ, the iron can occur as 2+, 3+ and even 4+. The oxygen content varies continually between SrFeO₂ (Fe²⁺) and SrFeO_{2.5} (Fe³⁺) and SrFeO₃ (Fe⁴⁺). The crystal lattice is distorted, yet the perovskite structure is preserved, as long as the composition does not deviate too much from the stoichiometric composition. The material can thus absorb or give off considerable amounts of oxygen, without changing too drastically in terms of the structure. A parallel exists to the storage materials for lithium ions in rechargeable Li-Ion batteries, such as LiFePO₄. Instead of the lithium content in LiFePO₄, the oxygen content is varied in SrFeO₃, and in both cases the iron ion changes the oxidation number thereof so as to preserve the charge neutrality.

In general, noble metals are particularly well-suited as electrodes for making contact with a p-type oxide as the channel or ion reservoir. In contrast, base metals such as indium or aluminum are particularly well-suited as electrodes for making contact with an n-type oxide (such as cerium-doped Nd₂CuO₄). Oxides having a high electrical conductivity, such as La₂CuO₄, SrRuO₃, or LaNiO₃, are materials that can be universally employed for electrodes. Using the example of La₂CuO₄, these oxides can, for example, be p-doped with bivalent cations such as Sr or Ba or n-doped with tetravalent cations such as cerium. The doping with impurity atoms then makes a considerably greater contribution to the electronic conductivity than the doping by way of oxygen deficit or oxygen surplus. The doping with impurity atoms thus causes the conductivity of normal-conducting oxides to become substantially independent of the oxygen content. However, the electrodes can also be high-temperature superconductors or comprise combinations of the materials listed here.

The distance between the source electrode and the drain electrode, which is bridged by the channel, advantageously ranges between 20 nm and 10 μm, and preferably between 20 nm and 1 μm. The channel is preferably designed as a thin layer having a thickness between 3 and 50 nm, and preferably between 5 and 20 nm. These measures, either individually or in combination with each other, reduce the capacitance of the channel and thus the charges that have to be transported both for changing (writing) and for measuring (reading) the electrical resistance of the same. This advantageously increases the writing and reading speeds.

In a particularly advantageous embodiment of the invention, the ion reservoir is connected to the channel via an ion conductor, the electronic conductivity of which is lower than the channel by at least two orders of magnitude. In the absence of a potential at the gate electrode as the driving force for the diffusion, the distribution of ions between the channel and the ion reservoir is thus particularly stable. The following rule of thumb should apply to the resistivities r_{L} of the ion conductor and r_{K} of the channel:

r_{L}>r_{K}*I²/(d_{L}*d_{K}),

where d_{L} and d_{K} are the thicknesses of the ion conductor and channel, respectively, and I is the length of the channel between the source electrode and the drain electrode. If the channel is shortened, the required resistivity r_{L} of the ion conductor decreases disproportionately. It is thus advantageous to laterally downscale the component, because this allows for more materials to be used as the ion conductor.

In a further particularly advantageous embodiment of the invention, in which the ion reservoir is able to exchange oxygen ions with the channel, the difference in potential between the gate electrode and channel plays a particularly important role as the driving force for the ion exchange. In all known ion conductors, the diffusion of oxygen ions is immeasurably slow at room temperature in the absence of a sufficiently strong electric field as the driving force. For example, this is the reason why fuel cells containing solid electrolytes, in which the only driving force that is available for oxygen ions to be conducted through the electrolyte is the voltage generated by the fuel ceil that is amounts to approximately 1 volt, are operated at temperatures of approximately 800 to 1000° C.

However, the ion conductor in a fuel cell is several 100 micrometers thick. In contrast, in the three-port component according to the invention, the ion conductor is advantageously 100 nanometers thick or less, preferably 50 nanometers or less, and still more preferably 30 nanometers or less. For an identical voltage drop across the ion conductor, a thickness of 100 nanometers amplifies the electric field a thousand times. Because this electric field supplies the activation energy for the ion transport, the transport increases disproportionately. It is thus possible to write information to the three-port component even at room temperature.

An ion conductor with electronic conductivity that is considerably lower than the ionic conductivity has the added effect that a potential that is applied to the gate electrode can be fully utilized for forming an electric field between the ion reservoir and the channel. If the ion conductor conducts electrons too well, some of the potential is short-circuited and is available only to a limited extent as the driving force for the exchange of ions. In addition, this prevents the channel from being short-circuited by the reservoir connected in parallel.

A corresponding solid electrolyte is particularly suitable as the ion conductor, the ion reservoir, and/or the channel. Notably, it was recognized that a solid electrolyte can combine good ionic conductivity with good electronic insulation between the ion reservoir and channel. Specifically, in every stable oxide having a low electronic conductivity, the transport of ions can generally be forced if the difference in potential between the gate electrode and the channel provides a sufficiently strong electric field. Examples of such materials include SrTiO₃, Sr₁₋ₓBaₓTbO₃, or Al₂O₃.

The solid electrolyte is advantageously a material in which the activation energy for the diffusion of oxygen ions at temperatures above 400° C. is less than 1 eV, and preferably less than 0.1 eV. Examples of such materials include yttria-stabilized zirconia (YSZ) and Mn- and/or Mg-doped LaGaO₃. Oxygen ions can be transported in such a material by site exchanges with lattice vacancies. For this purpose, they must overcome a potential barrier. Room temperature, at which the component according to the invention is typically used, provides only insufficient activation energy for overcoming this potential barrier. Consequently no oxygen transport takes place, and information that is written to the component is stable for a long time at room temperature. Only an electric field that is generated in the ion conductor by applying a potential to the gate electrode supplies the activation energy for the exchange of ions between the ion reservoir and channel. The ion current follows the equation I=I₀*exp(−[ΔH−0.5*q*d*E]/[k*T]), where I is the current, I₀ is a proportionality factor, ΔH is the activation energy for the jump from an occupied to an unoccupied lattice site (order of magnitude 1 eV), q is the amount of the charge of the transported ion (a multiple of the elementary charge), d is the jump distance of the ion from an occupied to an unoccupied lattice site (order of magnitude 200 pm), E is the field strength, k is the Boltzmann constant, and T is the temperature in Kelvin. In the range of a lower field strength, which is to say in high-temperature fuel cells (SOFC), for example, which is a key field of ion conductor application, the current is approximately proportional to the field strength, and the ion conductor follows Ohm's law. In the range of high field strength relevant for the present invention, however, the electric field makes a significant contribution to the activation energy. For this purpose, the field strength ranges between 0.01 and 1 GV/m, which is to say when an ion jumps to the neighboring vacancy in the direction of the Coulomb force, the energy barrier is reduced by 1/10 or more for the jump, which expedites the transport by orders of magnitude.

It is also possible to use for the component materials that have an electronic conductivity too high for SOFC applications. The shorter the channel becomes, the higher the conductivity of the ion conductor can be. The activation energy is particularly low at dislocations, grain boundaries, twin boundaries, stacking faults, and other extended lattice defects, and therefore the transport is facilitated along these defects.

The solid electrolyte is advantageously an amorphous material. Advantageously, this material does not tend toward crystallization and is chemically stable within a broad temperature range. Basically, there will be no grain boundaries, dislocations, or other defects in the solid electrolyte that could cause strongly varying properties in certain spots. The properties thereof are thus spatially homogeneous. If the material does not tend toward forming a crystalline order, defects of the type mentioned above will also not form even after a high number of write cycles. The properties of the material thus remain stable for a long time and do not degrade with operation. Examples of such solid electrolytes include GdScO₃, LaLuO₃, and HfO₂. GdScO₃ thin films are also stable for a short period (10 seconds to 20 seconds) at temperatures up to 1000° C. and remain amorphous.

The solid electrolyte is advantageously an oxide having an open structure, which is to say large interstitial sites or channels to which ions can drift. Examples of such materials include WO₃ and CBN-28 (Ca_{0.28}Ba_{0.72}Nb₂O₆).

The ion conductor and/or the solid electrolyte advantageously exhibit an anisotropic ionic mobility. For this purpose, the conductor and/or electrolyte may contain one-dimensional channels, for example, in which dopants are intercalated. However, it can also contain interfaces between different materials, along which ions can move in two dimensions between the ion reservoir and the channel. It is advantageous if the channels and/or interfaces meet with the channel substantially perpendicularly to the flow direction through the channel. Ions are then essentially injected into or withdrawn from the channel only where the channels and/or interfaces meet. The ion content of the weak link in a Josephson junction can thus be influenced in a targeted manner, for example, without changing the superconducting electrodes, which are separated by the weak link.

Anisotropic ionic mobility can be achieved, for example, by providing the ion conductor or solid electrolyte with a layer structure, wherein the ionic transport along these layers is favored over the transport perpendicularly to these layers by at least one order of magnitude. Examples of such materials include yttrium barium copper oxide (YBa₂Cu₃CO₇₋ₓ) and lanthanum barium copper oxides (La₂CuO₄₋ₓ).

If such an ion conductor or solid electrolyte is to exchange ions with a neighboring material, it is advantageous for the interface with the neighboring material to intersect the layers. This can be controlled by the crystal orientation of the substrate surface in conjunction with the growth parameters, notably the substrate temperature. Such a growth process is described in Divin et al. (Y. Y. Divin, U. Poppe, C. L. Jia, J. W. Seo, V. Glyantsev, “Epitaxial (101) YBa₂Cu₃CO₇ thin films on (103) NdGaO₃ Substrates”, Conference Paper “Applied Superconductivity”, Spain, Sep. 14 to 19, 1999).

The electronic conductivity generally has the same preferred directions as the ionic conductivity.

Instead of oxygen ions, it is also possible to use other ions for switching. Suitable solid electrolytes for silver cations include, for example, silver iodide, rubidium silver iodide, and silver sulfide. WO₃ or Na₃Zr₂Si₂PO₁₂ (NASICON) may be used for alkali cations, for example. Certain polymers, such as Nafion, have a high conductivity for protons.

With regard to the write process, the total number of transported ions is what matters. So as to achieve this total count, a lower voltage can be applied to the gate electrode for an extended period or a higher voltage can be applied for a shorter period. The transport of ions through a solid electrolyte is a non-linear effect in the range of a high field strength. If a higher voltage drop occurs across the solid electrolyte, a disproportionately higher number of ions is transported per unit of time. The write speed can thus be significantly increased when a short pulse having a higher write voltage is applied to the gate electrode.

The gate electrode and channel form a capacitor that is charged by the charge transport between the gate electrode and channel. If the electronic resistance of the ion conductor is very high, this capacitor discharges only very slowly. It may then be advantageous, after having applied the short pulse with the high write voltage, to apply a longer pulse having a considerably lower voltage and opposite polarity. This discharges the capacitor formed by the gate electrode and the channel, but cancels only a small portion of the ion transport that previously occurred between the gate electrode and the channel because this transport progresses disproportionately more slowly at low voltages.

The potential in the ion conductor along the path from the ion reservoir to the channel advantageously has an asymmetrical progression. EP 1 012 885 B1, for example, describes how such a potential landscape can be implemented. The activation energy for the ion transport through the ion conductor then depends on the direction of transport. The activation energy that must be applied for the ion transport from the ion reservoir to the channel significantly differs from that which must be applied for the opposite ion transport from the channel to the ion reservoir. For example, the ion transport from the ion reservoir to the channel may be preferred over the opposite path in terms of the energy. Activation energies then exist at which the ion conductor is transmissive for ions in substantially only one direction and thus acts as an ion rectifier. This can be implemented, for example, by producing the ion conductor and/or the channel from at least 3 multi-layers, the potential profiles of which form a superlattice.

The ion reservoir can function as an ion conductor at the same time, which simplifies the production of the three-port component. However, a tradeoff then exists between the property as an ion reservoir, the charge state of which must be variable with ions, and the property as an ion conductor, which should not change the stoichiometry thereof and should maintain a low electronic conductivity. Examples of materials that can give off cations and/or anions to the channel while preserving the charge neutrality and, nonetheless, maintain a comparatively low electronic conductivity, include LaMnO₃, EuScO₃₋ₓ, EuTiO₃₋ₓ, and LaNiO₃₋ₓ. The oxygen content of these materials can be varied by a variable valence of a cation.

Many oxides, such as TiO₂₊ₓ, for example, can be converted from an electronic n-type conductor (oxygen deficit, x>0) to an electronic p-type conductor (oxygen surplus, x<0), via an insulator (stoichiometric composition, x=0), by raising or lowering the oxygen content. In a particularly advantageous embodiment of the invention, the channel thus comprises a metal oxide having an electronic resistance that can be varied by at least one order of magnitude by supplying ions to or removing ions from the ion reservoir. This can be achieved, for example, if the metal oxide, in the stoichiometric composition thereof, is an electronic insulator and becomes conductive when it deviates from this composition (or conversely). This metal oxide advantageously has a perovskite structure. It can then be implemented particularly well as an epitaxial layer system on an oxide monocrystal as the substrate. Suitable substrates include, for example, SrTiO₃, LaAlO₃, MgO, or NdGaO₃.

So as to be able to exchange ions between the channel and the ion reservoir at a speed that is sufficient for memory applications, both the channel and the ion reservoir should exhibit sufficient conductivity for the ions of at least 2*10⁻⁶ Sm⁻¹ at a field strength of 1 GV/m. The required conductivity for a particular application can be calculated based on known transport laws from the number of ions to be transported, the available field strength, the desired switching time, and geometric factors. For most applications using a Josephson junction, such as in a superconducting quantum interference device (SQUID), for example, switching times of up to the range of 1 minute will suffice, which are considerably longer than in a memory.

In a particularly advantageous embodiment of the invention, the ion reservoir and the channel comprise semiconductors with doping of the same type (p or n), and the ion conductor comprises a semiconductor with the opposite doping. It is then possible to use materials for the channel, the ion reservoir, and the ion conductor that are similar and thus compatible with each other during production. It is even possible to use the same material, with the difference between the channel, ion reservoir, and ion conductor residing only in the different doping. From a stoichiometric perspective, this difference then exists only in the quantities of dopants used, with the concentrations of the dopants for oxides generally being only in the percentage range. The p-n junctions between the channel and ion conductor and between the ion conductor and ion reservoir can additionally provide for the electrical insulation of the channel.

In a further advantageous embodiment of the invention, an ion conductor can be entirely dispensed with. In this embodiment, the ion reservoir and the channel comprise semiconductors with doping of the same type (p and n). With a suitable distribution of the ions, the ion reservoir can then act as part of the channel. For example, if the ion reservoir is n-conducting and the channel is p-conducting, the conductivity of the ion reservoir and that of the channel increase simultaneously if oxygen ions are transported from the n-conducting to the p-conducting region. If oxygen ions are transported in the opposite direction, the conductivity of the ion reservoir and that of the channel decrease simultaneously in a corresponding manner.

In a particularly advantageous embodiment of the invention, at least one section of the channel has a jump temperature below which it is superconducting. The properties of this superconductor, which according to the existing prior art are established by material constants, can then be varied by applying a potential to the gate electrode. It is possible to vary, in particular, the critical current and the normal-conducting resistance, which develops when the critical current is exceeded. It is possible, for example, to tune oscillating circuits in sources or detectors or oscillators for terahertz frequencies. It is even possible to switch a thin film back and forth between the superconducting and normal-conducting states. According to existing prior art, it has been possible to switch superconductors and Josephson junctions between the normal-conducting state and the superconducting state only locally by way of an electric field, a magnetic field or laser radiation. Contrary to the switching that is made possible according to the invention, these effects were purely electronic in nature and therefore volatile. According to the invention, however, non-volatile reversible switches or components having adjustable properties can be implemented using superconductors.

The superconducting section can be implemented as a monocrystal. In particular the entire channel between the source electrode and drain electrode can be implemented as a superconducting monocrystal. However, the superconducting section may also contain a variety of defects, which are electrically connected in series, for example by not being located in parallel to the current path between the source electrode and the drain electrode. They can notably be located transversely to this current path. Such defects can especially include grain boundaries, stacking faults, and twin boundaries. The ions are preferably conducted out of the ion conductor and the channel at the defects, and the switching effect is multiplied by the series connection of the grain boundaries as weak links. The non-parallel orientation of the defects relative to the current path prevents a short-circuit from developing between the source electrode and the drain electrode.

Even if the section is not superconducting, for example if it is above the critical temperature Tc thereof, or quite generally speaking is not made of a superconducting material at all, the electrical resistance of the channel is decisively determined by the charge of the grain boundaries with ions, and can thus be varied deliberately by way of the charge.

As an alternative, the defects may also run parallel to the current direction in the channel. While they cannot serve as weak links in this case, they can facilitate the ion exchange of the channel with the ion conductor or the ion reservoir.

The switching of superconducting properties by way of ion transport has an effect in particular in a further particularly advantageous embodiment of the invention. In this embodiment, two sections of the channel, which are superconducting below a jump temperature, are spaced from each other by a barrier that is able to exchange ions with the ion reservoir. The barrier can notably be a weak link, so that the two sections of the channel, together with the weak link, form a Josephson junction. The weak link can exist in particular in a grain boundary between the superconducting sections. Both the macroscopic conductivity of the barrier and the quantum-mechanical barrier height for the Cooper pairs tunneling between the superconducting sections can then be adjusted by supplying ions to and removing them from the weak link by the application of the suitable potential to the gate electrode. Especially the critical current and the resistance in the normal-conducting state, as the fundamental parameters of any Josephson junction, can be adjusted in this way. Such tunable Josephson junctions can be used in quantum-electronic components, and more particularly in superconducting quantum interference devices (SQUIDs) or in high-frequency components for terahertz electronics, for example in sources (oscillators) or detectors for radiation in the frequency range between 0.1 and 10 THz. Radiation in this frequency range is required, for example, for the chemical analysis of samples by means of Hilbert spectroscopy. Tunable Josephson junctions according to the invention can also be used in digital circuits based on rapid single flux quantum (RSFQ) technology or in quantum computers.

The jump temperature is advantageously above 77 K. This allows cooling with liquid nitrogen. Examples of high-temperature superconductors which can be used in the three-port component according to the invention include cuprates, and more particularly cuprates having the formula RBa₂Cu₃O₇₋ₓ or alkaline earth-doped cuprates having the formula R₂CuO₄₊ₓ, with R being a rare earth metal or a combination of rare earth metals. R can notably be a rare earth metal from the group (Y, Nd, Ho, Dy, Tb, Gd, Eu, Sm). It is also possible to use Bi—, Tl— and Hg—Cu oxides as high-temperature superconductors. Iron-based pnictides and oxypnictides are also conceivable, if they achieve a sufficiently high jump temperature. Jump temperatures of up to only approximately 55 K have been reached so far for iron pnictides.

In a further advantageous embodiment of the invention, the channel comprises a material which can be converted from a normal conductor to a superconductor, and still more preferably to a semiconductor, by varying the oxygen content or fluorine content thereof. Such materials include, for example, iron oxides or copper oxides, which additionally contain one or more alkaline earth metals such as La₂CuO₄₊ₓ, (Sr, Ba, Ca)CuO₂₊ₓ, La₂CuO₄Fₓ or (Sr, Ba, Ca)CuO₂Fₓ.

The properties of the channel, ion reservoir, and/or ion conductor can be tailored by way of deliberately generated defects (grain boundaries, dislocations, or stacking faults) and by deliberately orienting the crystal lattice. A Josephson junction, for example, can be implemented as a channel by disposing two sections made of one and the same superconducting material having differing crystal orientations so as to adjoin each other. The grain boundary between the two sections then forms the barrier. In addition, crystal lattice can be oriented so that the direction having high ion mobility coincides with the switching field direction.

Specifically high-temperature superconducting cuprates are particularly advantageous for implementing a grain boundary Josephson junction. In these cuprates, the oxygen is preferably transported along grain boundaries and in the CuO chain planes between the layers. If the layers are oriented parallel to the interface between the channel and the ion conductor, and more particularly parallel to the crystal orientation of the substrate, only few ions can cross the interface between the superconducting sections of the channel and the ion conductor. The ion exchange between the channel and the ion reservoir via the ion conductor is then concentrated substantially on the grain boundary between the superconducting sections of the channel, the grain boundary at the same time forming the weak link of the Josephson junction. However, it is precisely the properties of this weak link that are supposed to be varied by the ion exchange. The effect can be further amplified if the grain boundary in the channel adjoins a grain boundary in the ion conductor.

Advantageously contact is established between the interface of the weak link facing away from the ion conductor and a second gate electrode. If a potential is also applied to this gate electrode, the potential preferably having a different polarity than the potential which is applied to the first gate electrode, the voltage dropping on an overall basis across the ion conductor, and thus the transport of ions, can be increased.

The materials of the channel, ion reservoir and/or ion conductor can be present in pure form or they can be doped with suitable elements, so as to optimally adjust the properties, such as the electrical conductivity or the ion conductivity, for example. They can be present in a stoichiometric composition, or they can have an increased or decreased content of one or more elements, such as oxygen, for example, as compared to this composition. The content of the channel can advantageously be increased or decreased in particular with regard to that element, the ions of which can be exchanged between the channel and the ion reservoir. In this way, a working point of the three-port component can be pre-set. The properties of the channel can then be varied around this working point by applying a voltage to the gate electrode.

The channel, ion reservoir, and/or ion conductor can be implemented as thin films on a substrate. They can, for example, be produced by way of sputtering (notably high-pressure oxygen sputtering), vapor deposition, PLD, or CVD.

In a particularly advantageous embodiment of the invention, the channel comprises a conductive interface between two materials having lower conductivity by at least one order of magnitude. This interface can, for example, be a two-dimensional electron gas. However, it can also be created by way of interdiffusion between mutually adjoining materials which dope one another. These materials can notably be semiconductors.

A conductive interface is created, for example, between lanthanum aluminum oxide (LaAlO₃) and strontium titanium oxide (SrTiO₃). This interface has not only high electronic mobility, but is also extremely thin. Consequently only few ions need be supplied or removed in order to drastically vary the conductivity of such a channel. This is possible within a very short time, whereby the component comprising such a channel is a particularly fast switch.

As high a switching speed, and consequently write speed, as possible is especially important when the component is used to implement a memory which is destructively read, analogous to the conventional DRAM. It is then necessary to rewrite the information again every time it is read out. To this end, the reversibility of the storage in the component according to the invention over a very large number of write cycles is advantageous.

So as to facilitate the writing of information to the three-port component, the same can be briefly heated by applying an elevated current pulse to the channel or by using a separate heating cable that is provided for this purpose. The ion conductor, the temperature of which plays an important role during writing, can be heated, notably at the same time, by resistively heating the channel and by the current pulse that is applied to the gate electrode for the write process.

The component, for example, can be produced using high resolution lithography and chemical and/or physical etching methods. A suitable etching agent for La₂CuO₄ and YBa₂Cu₃O₇₋ₓ is an ethanolic solution of bromine, for example. Anhydrous etching agents are generally advantageous because several of the mixed oxides hydroiyze and form hydroxides, which negatively affect the surface.

The component is advantageously produced in a protective gas atmosphere. This prevents the channel, the ion reservoir, and/or the ion conductor from absorbing moisture and/or CO₂ or other gases from the environment. After the production and before the removal, the component may be provided with a thin cover layer, for example made of strontium titanium oxide, so as to prevent the absorption of moisture and other degradations of the surface. Strontium titanium oxide has been found to be effective in experiments conducted by the inventors in a thickness as low as 1 nm.

After production, the component can be heat-treated in a defined atmosphere. This can, for example, cause an interdiffusion of dopants in the respective material to be doped so as to homogeneously distribute the doping in the material. However, it is also possible to fill the ion reservoir with oxygen ions, for example. If this is not possible using molecular oxygen alone, charging can be supported by using a microwave plasma, atomic oxygen, or ozone.

In general, it is not absolutely essential for the functioning of the component that the interfaces between the ion reservoir, ion conductor, and channel are absolutely sharply defined. All components can rather also be implemented as multi-layers or gradient layers.

The materials for the ion reservoir, ion conductor, and channel are generally not elements, but compounds. If these compounds are epitaxially grown onto a substrate, the respective surface contains an excess of the element with which the epitaxy ended. This element can be used as the dopant for the next component to be applied.

The affinity of materials applied in the form of layers for the ion transport can be deliberately influenced during the production of the component by mechanically stressing the substrate while the layers are being applied. Channels, along which ions are transported, may thus be expanded, which is favorable for the ion transport.

### SPECIFIC DESCRIPTION

The subject matter of the invention will be described in more detail hereafter based on figures, without thereby limiting the subject matter of the invention. In the drawings:

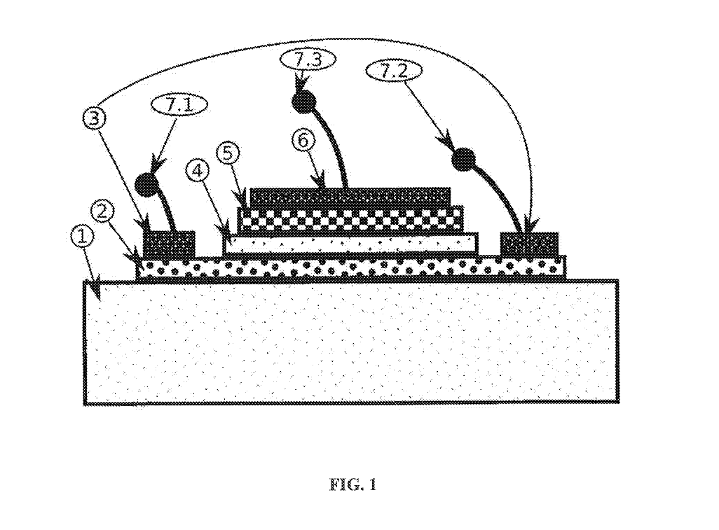

FIG. 1: shows a cross-section of an exemplary embodiment of the three-port component according to the invention;

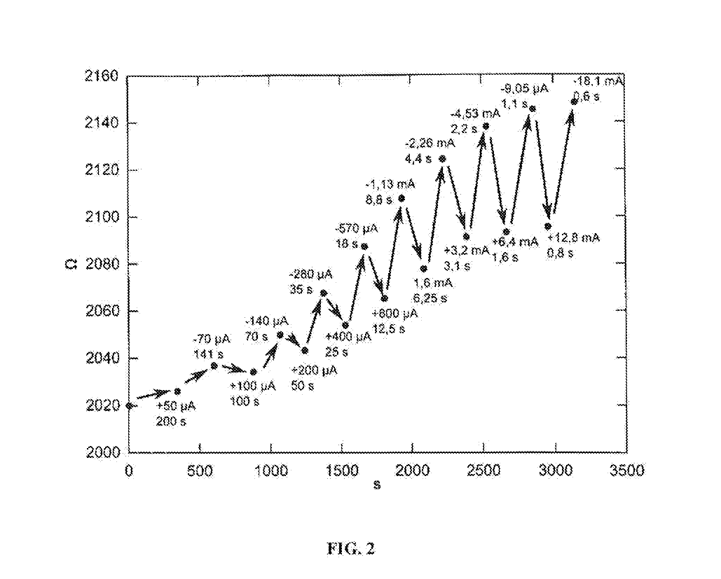

FIG. 2: shows the change of resistance between the source electrode and drain electrode of a component according to the invention after successively applying gate voltages that increase in terms of magnitude, and alternate in terms of the polarity, in each case the same charge of 10 mC having been transported;

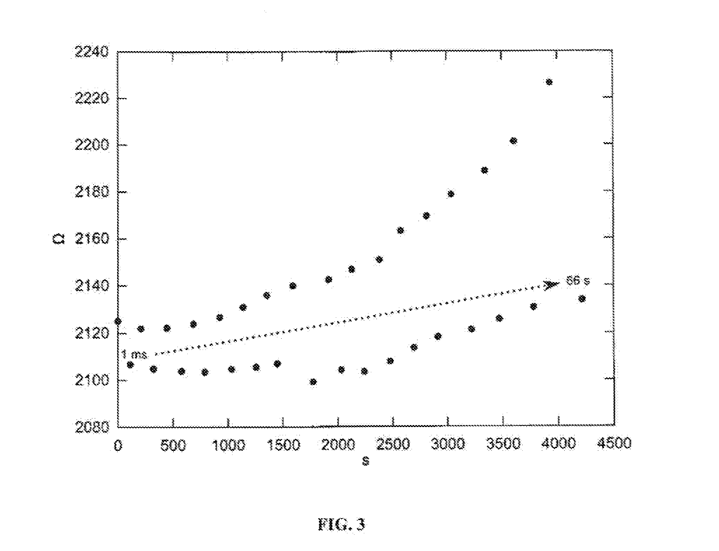

FIG. 3: shows the change of resistance between the source electrode and drain electrode of a component according to the invention after successively applying currents that alternate in terms of the polarity, but have the same magnitudes, for an increasing duration;

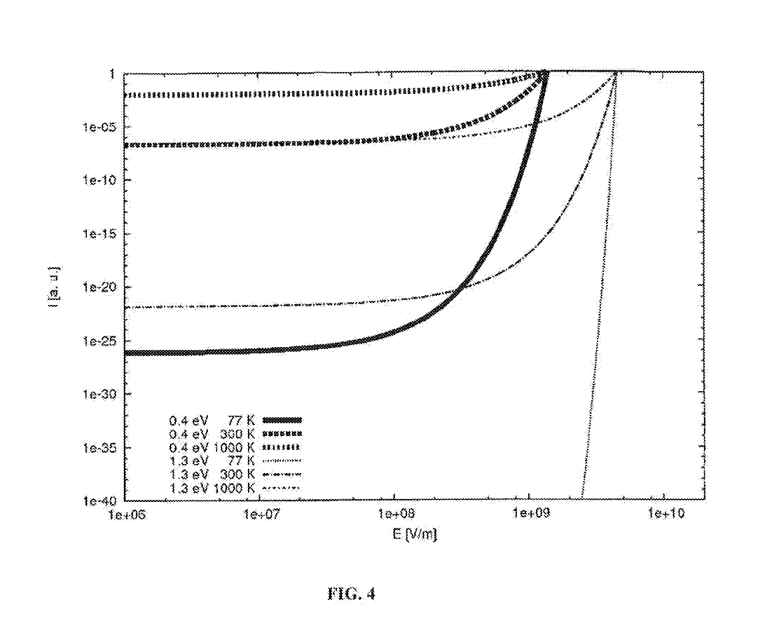

FIG. 4: shows the calculation of the field-dependent ion current I for two hypothetical materials with an activation energy ΔH of 0.4 eV and 1.3 eV, respectively, for the jump from an occupied lattice site to the next unoccupied lattice site, shown for three different temperatures;

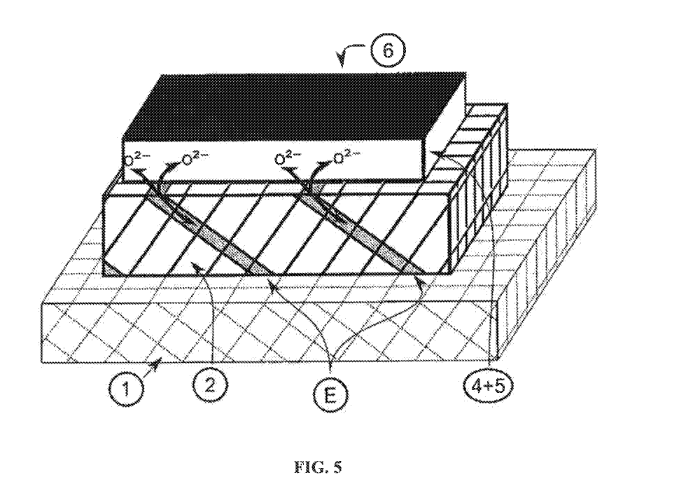

FIG. 5: shows a further exemplary embodiment of the three-port component according to the invention, comprising a channel that exhibits anisotropic ion conductivity; and

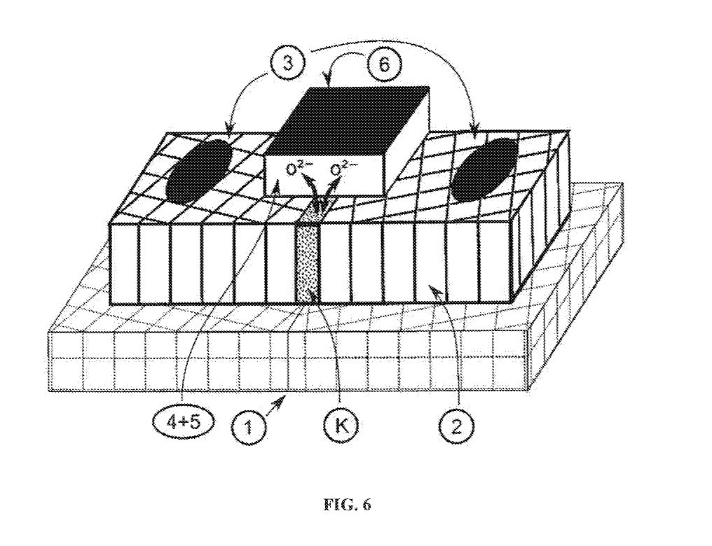

FIG. 6: shows a further exemplary embodiment of the three-port component according to the invention, comprising a channel that is designed as a Josephson junction.

FIG. 1 shows a sketch of a cross-section of an exemplary embodiment of the three-port component according to the invention. The channel 2, which connects two electrodes 3 (source electrode and drain electrode) to each other, is implemented as a thin film on the insulating substrate 1. An ion conductor 4 and an ion reservoir 5 are structured on the channel 2, likewise as thin films. A contact is established between the ion reservoir and a gate electrode 6. When a potential is applied to this gate electrode by way of the feed line 7.3, the ion reservoir 5 can exchange ions with the channel 2 through the ion conductor 4, while remaining electronically insulated from the channel. This changes the electronic conductivity of the channel 2. Information can thus be deposited in the three-port component. The information can be read out again by applying a read voltage to the electrodes 3 connected to the channel 2 via the feed lines 7.1 and 7.2 and measuring the current that is driven through the channel 2. The layer sequence may also be inverted with regard to the substrate, so that the gate electrode is deposited first on the substrate and the channel is thus located at the top.

The components that were used for the following tests were produced using shadow masks through which the layers were deposited on the substrate in a locally defined manner. The channel made of La₂CuO₄ was 2 mm wide, 5 nm thick and bridged a distance of 1 mm between the source electrode and drain electrode. The ion conductor made of SrTiO₃ was approximately 10 nm thick. The source electrode, drain electrode, and gate electrode were produced from La_{1.85}Sr_{0.15}CuO₄ having good conductivity. The gate electrode at the same time constitutes the oxygen ion reservoir. The component was implemented on a rhombohedral LaAlO₃ (100) substrate.

In FIG. 2, the resistance between the source electrode and drain electrode is plotted for this component after successively applying higher magnitude voltages to the gate electrode over the time of the experiment. The respective algebraic sign of the voltage that was applied to the gate electrode changed between two applications, whereby the resistance between the source electrode and drain electrode alternately increased and decreased. The voltages were selected so that the product of the current that is driven through the ion conductor and the pulse duration always yields the same transported charge of 10 mC. The current and pulse duration is noted on each measurement point.

The change of resistance visibly increases as the applied voltage rises, although the same charge is being transported. This is proof that the transport of the ions is a non-linear effect, and the ions distribute better in the ion conductor and in the channel when the voltage is greater.

Despite the high transported charge density of 5000 C/m², the resistance between the source electrode and the drain electrode changes only by approximately 2%. The partial ionic conductivity which can thus be achieved overall is very low. The inventors attribute this to the fact that the component is a macroscopic “proof of concept,” the production of which still offers considerable potential for improvement, for example by downscaling the component laterally to micrometer or even nanometer dimensions.

The saturation of the effect at this low switch amplitude indicates that switching takes place in certain spots, for example at defects. In addition, the channel appears to have been doped by interdiffusion during production, whereby the resistance thereof is unexpectedly low and can be varied less, in percentage terms, by oxygen deposits.

In FIG. 3, the component which was examined in FIG. 2 was again switched with alternating polarities. The arrows drawn in FIG. 2, which illustrate the sequence of the measurement points, have been omitted in FIG. 3 for the sake of clarity. The same current always flowed through the ion conductor, except for times having differing durations between 1 ms and 66 s, so that a greater charge was transported with longer switching times. In 1 ms, the component switches by 1% of the total resistance, and in 66 s it switches by slightly more than 4%.

In accordance with the equation I=I₀*exp(−[ΔH−0.5*q*d*E]/[k*T]), FIG. 4 shows the calculated field-dependent ion current I for two hypothetical materials with an activation energy ΔH of 0.4 eV (very low value for oxygen ion conductor) and 1.3 eV (comparatively high value for oxygen ion conductor) for the jump from an occupied site to the next unoccupied lattice site. The calculation was carried out for three different temperatures (liquid nitrogen, room temperature, and SOFC operating temperature). The transport is disproportionately accelerated starting at approximately 100 MV/m. This corresponds approximately to the field strengths at which the material short-circuits electronically.

It is apparent that a material having a lower activation energy is more favorable, because the transport is drastically accelerated even at a lower field strength. The maximum field strength achievable in the material is limited by the electronic conductivity thereof. The higher this conductivity is, the greater is the current which is required to maintain a predetermined difference of potential, and thus a field strength, across the material. This current increases disproportionately with the field strength. The limit for the achievable field strength is reached when the material short-circuits electronically.

FIG. 5 shows a perspective drawing of a sketch of a further exemplary embodiment of the three-port component according to the invention. In this embodiment, the channel 2 and the ion conductor 4, which also acts as the ion reservoir 5, are implemented in the form of epitaxial layers on a monocrystailine substrate 1. The boundaries of the unit cells of the substrate 1 and channel 2 are indicated by the hatching to illustrate the respective crystal orientations. The crystal structure of the channel material, such as YBa₂Cu₃O₇₋ₓ or La₂CuO_{4 x}, is layer-like with high oxygen mobility in preferred crystal planes E, which here are shaded. This results in a strong anisotropic ion conductivity. The conduction of the channel along the preferred crystal planes E is better by a factor of 1000 than perpendicularly to these planes. Ions can therefore be exchanged between the ion conductor/reservoir and the channel 2 preferably along this plane E.

The orientation of the planes E relative to the substrate surface is determined by the crystal orientation of the substrate surface in cooperation with the growth parameters. The preferred planes E are advantageously oriented so that the electric field that is created in the ion conductor/reservoir by applying a potential to the gate electrode 6 can be broken down into a linear combination in which one component is parallel to the preferred planes E. This should also apply to the preferred planes E of the ion reservoir 4 or the ion conductor 5, provided the ion reservoir 4 and/or the ion conductor 5 likewise exhibit anisotropic ion conductivities.

If the channel material is YBa₂Cu₃O₇₋ₓ, the preferred planes E are the CuO chain planes. If the channel material is La₂CuO₄₊ₓ, the preferred planes E are planes from the interstitial sites between the LaO planes.

So as to achieve a low electronic resistance of the channel 2 between the source and drain electrodes (not shown), it is advantageous to apply the electrodes on the front and back edges of the channel in the figure shown. The source-drain current then flows perpendicularly through the drawing plane. The planes having a high electronic conductivity of the example materials, which run parallel to the planes E having high oxygen mobility, are thus located without interruption in the current path.

FIG. 6 shows a perspective drawing of a sketch of a further exemplary embodiment of the three-port component according to the invention. In this embodiment, the channel 2 is designed as a Josephson junction and implemented in the form of epitaxial layers on a bicrystal substrate 1. A grain boundary K generated in a targeted manner forms the weak link in the superconducting channel 2. Two electrodes 3 (source electrode and drain electrode) are in contact with the channel. The weak link can exchange oxygen ions with the ion reservoir 4 or the ion conductor 5 when a potential is applied to the gate electrode 6. The electronic properties of the same can thus be varied when it is installed. The boundaries of the unit cells, these being the substrate 1 and the channel 2, are indicated by the hatching as in FIG. 5.

1. A three-port component comprising a source electrode, a drain electrode, and a channel, which is connected between the source electrode and the drain electrode and is made of a material having an electronic conductivity that can be varied by supplying and/or removing ions, comprising an ion reservoir which is in contact with a gate electrode and which is connected to the channel so that the reservoir is able to exchange ions with the channel when a potential is applied to the gate electrode.

2. The three-port component according to claim 1, wherein the ion reservoir is a solid body under standard conditions.

3. The three-port component according to claim 2. wherein the ion reservoir comprises at least one cation and/or anion having variable valence.

4. A three-port component according to claim 1, wherein the ion reservoir is connected to the channel via an ion conductor, the electronic conductivity of which is less than that of the channel by at least one order of magnitude.

5. The three-port component according to claim 4, wherein the activation energy for the ion transport through the ion conductor depends on the direction of transport.

6. The three-port component according to claim 4, wherein the ion conductor has a thickness of 100 nanometers or less.

7. A three-port component according to claim 4, wherein the ion reservoir is also the ion conductor.

8. A three-port component according to claim 1, wherein the ion conductor, the ion reservoir, and/or the channel comprise a respective solid electrolyte.

9. The three-port component according to claim 8, wherein the solid electrolyte, is a material in which the activation energy for the diffusion of oxygen ions at temperatures above 400° C. is less than 1 eV, and more preferably less than 0.1 eV.

10. A three-port component according to claim 1, wherein the ion conductor and/or the solid electrolyte exhibit anisotropic ionic mobility.

11. A three-port component according to claim 1, wherein the channel comprises a metal oxide having an electronic resistance that can be varied by at least one order of magnitude by supplying or removing ions from the ion reservoir,

12. A three-port component according to claim 1, wherein the ion reservoir and the channel comprise semiconductors with doping of the same type (p or n) and the ion conductor comprises a semiconductor with the opposite doping.

13. A three-port component according to claim 1, wherein the ion reservoir and the channel comprise semiconductors with opposite doping (p or n).

14. A three-port component according to claim 1, wherein the distance between the source electrode and the drain, electrode bridged by the channel ranges between. 20 nm and 10 μm.

15. A three-port component according to claim 1, wherein the channel is designed as a thin film having a thickness between 3 and 50 nm.

16. A three-port component according to claim 1, wherein the ion reservoir is able to exchange oxygen ions with the channel.

17. A three-port component according to claim 1, wherein the channel, the ion reservoir, and/or the ion conductor either have a respective crystal structure, which does not change during the exchange of ions between the ion reservoir and the channel, or is amorphous.

18. A three-port component according to claim 1, wherein the content of the material of the channel is increased or decreased over the stoichiometric composition thereof with regard to that element, the ions of which can be exchanged between the channel and the ion reservoir.

19. A three-port component according to claim 1, wherein the channel comprises a conductive interface between two materials having lower conductivity by at least one order of magnitude.

20. A three-port component according to claim 1, wherein at least one section of the channel has a jump temperature below which the section is superconducting.

21. The three-port component according to the claim 20, wherein a plurality of defects are electrically connected in series in the section.

22. The three-port component according to claim 20, wherein two sections of the channel, which are superconducting below a jump temperature, are spaced from each other by a barrier that is able to exchange ions with the ion reservoir.

23. The three-port component according to claim 22, wherein the channel is designed as a Josephson junction, the weak link of which is the barrier.

24. The three-port component according to claim 22, wherein the sections are made of the same superconducting material, but have different crystal orientations, so that the grain boundary between the sections forms the barrier.

25. A three-port component according to claim 22. wherein the sections have the same crystal orientation as the substrate on which they are disposed.

26. A three-port component according to claim 20, wherein the jump temperature is above 77 K.

27. A three-port component according to claim 20, wherein the channel is a cuprate, and more particularly a cuprate having the formula RBa₂Cu₃O₇₋ₓ or an alkaline earth-doped cuprate having the formula R₂CuO₄₊ₓ, where R is a rare earth metal or a combination of rare earth metals.

28. A three-port component according to claim 20, wherein the channel comprises a material from the class of iron pnictides or iron oxypnictides.

29. A three-part component according to claim 20, wherein the channel comprises a material that can be converted from a normal conductor to a superconductor .by varying the oxygen content or fluorine content thereof.

30. A quantum-electronic component; and more particularly a superconducting quantum interference device, or source or detector for electromagnetic radiation in the frequency range between 0.1 and 1.0 THz, comprising at least one three-port component according to claim 21.
